(19) United States
(12) Patent Application Publication
(10) Pub. No.: US 2008/0142252 A1
(43) Pub. Date: Jun. 19, 2008

(54) Solid via with a contact pad for mating with an interposer of an ATE tester

(76) Inventors: Romi Mayder, San Jose, CA (US); Kris Rexroad, San Jose, CA (US); Pamela Stellmacher, Cupertino, CA (US)

Correspondence Address: VERIGY, LTD., IP LEGAL DEPARTMENT, 10100 N. TANTAU AVENUE, CUPERTINO, CA, 95014-2540, US

(21) Appl. No.: 11/638,884

(22) Filed: Dec. 13, 2006

(51) Int. Cl. H05K 1/09; H05K 1/11

(52) U.S. Cl. 174/256; 174/262

(57) ABSTRACT

An epoxy filled via hole in a printed circuit board is presented. The epoxy filled via hole may have metal plating between the epoxy and the via hole walls of the printed circuit board. The epoxy filled via hole may have a land pad directly over the epoxy filling, creating a compact contact area for an ATE interposer.

### BACKGROUND

In today's high density printed circuit board assemblies, in order to connect one layer to another using a conventional multilayer printed circuit board, via holes are generally drilled through the entire board thickness. During testing, an interposer 10 is mated to an ATE tester 20 with a printed circuit board 150 using contacts 100 to access various circuits, elements and features (note shown) on the board for testing. Some circuit elements may be on the back side of the board or otherwise not readily accessible on the top side of the printed circuit board. It is desirable to utilize the via holes to access various circuit elements with the tester interposer during test.

However, via holes are not solid and therefore, cannot be used to mate mechanically with interposer contacts. Thus, for some electrical contacts, there must be a land pad, a dog bone trace, and a via hole, as shown in FIG. 1. FIG. 1 shows a standard substrate material 150 with a via 140 having via pads 130. Typical via pads are made of 0.5 oz copper, 200 uin electroplated Nickel, and 50 uin of electroplated Cobalt Gold (CoAu). In order to permit an interposer contact 100 of an automatic tester, such as the Verigy 5400 to make contact with the via 140, a land pad 110 must be connected to via 140 by means of via pads 130 and a dog bone trace 120. The land pad 110 is typically made of 0.5 oz copper, 200 μin electroplated Nickel, and 50 μin of Cobalt Gold (CoAu) and the dog bone trace 120 is typically made of 0.5 oz copper, 200 uin electroplated Nickel, and 50 μin of Cobalt Gold (CoAu) Via 140 is essentially hollow.

As will be readily apparent from FIG. 1, this arrangement significantly limits the density of land pads that can be placed in a given area of a printed circuit board, and thus significantly limits the density of the printed circuit board itself, as more circuitry would require more vias and more external access to I/O, testing, etc. To increase the density of the land pads, and thus the density of the board, the via holes have been made smaller and smaller over time. This has reduced the overall thickness of the printed circuit boards, as the maximum board thickness is related to the via hole diameter through a parameter known as the aspect ratio. The printed circuit board can only be about 15-36 times thicker than the smallest via hole diameter. This has also reduced the current carrying capabilities of these via holes.

It is desirable to have printed circuit boards capable of denser land pads and vias, while supporting larger diameter vias; thicker printed circuit boards; more layers in the printed circuit board; more signals routed to contact pads; more reliable current carrying capabilities of vias; and reduced crosstalk between signals on adjacent layers.

### BRIEF DESCRIPTION OF THE DRAWINGS

An understanding of the present teachings can be gained from the following detailed description, taken in conjunction with the accompanying drawings of which:

FIG. 1 illustrates a typical interposer contact contacting a land pad of a via on a substrate.

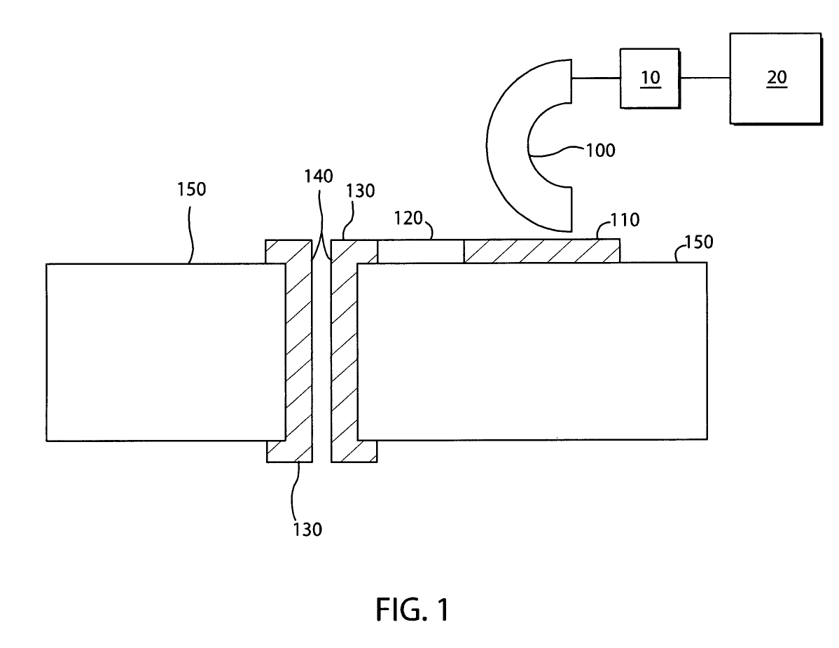

FIG. 2 illustrates an interposer contact contacting a land pad of a via on a substrate in accordance with the present teachings.

FIG. 3 illustrates a flow chart of a method in accordance with the present teachings.

### DETAILED DESCRIPTION

In the following detailed description, for purposes of explanation and not limitation, example embodiments disclosing specific details are set forth in order to provide a thorough understanding of the present teachings. It is apparent to one having ordinary skill in the art with benefit of the present disclosure that other embodiments according to the present teachings that depart from the specific details disclosed herein remain within the scope of the appended claims. Moreover, descriptions of well-known apparatus and methods may be omitted so as to not obscure the description of the example embodiments. Such methods and apparatus are considered within the scope of the present teachings.

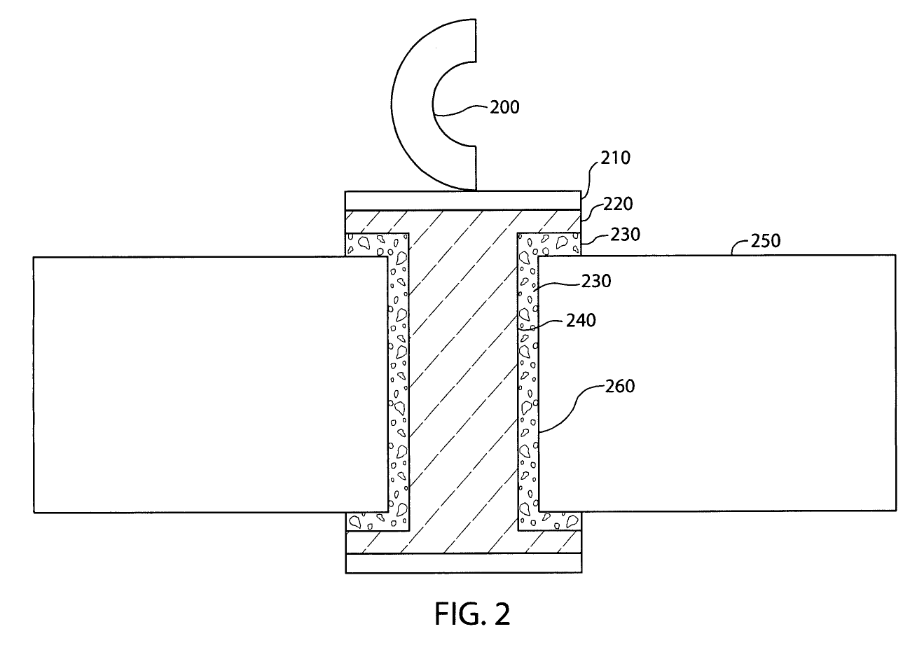

With specific reference to FIG. 2, a large via 260 in accordance with the present teachings is illustrated. Specifically, FIG. 2 shows a high temperature substrate 250, which may be made of FR-4, Al2O3, FR-5, Polyimide, Park-Nelco 4000-13 or other similar known material with a via 260, which may be plated with a metal, metal compound or metal composite material 230, such as copper, Be—Cu or other similar material and filled with an epoxy paste material 240, such as copper epoxy, silver epoxy or other conductive or non-conductive material with a coefficient of thermal expansion that is close to that of the printed circuit board material. The filled via 260 may than be electro-plated 220 with nickel or other known plating metal, metal compound or metal composite that is approximately 200 μin thick and than plated 210 with gold, Cobalt Gold (CoAu), or a similar noble metal or noble metal composite material that is approximately 50 μin thick. The tester interposer contact 200 may than make physical and electrical contact with the land pad 210, which is substantially directly over the large via 260.

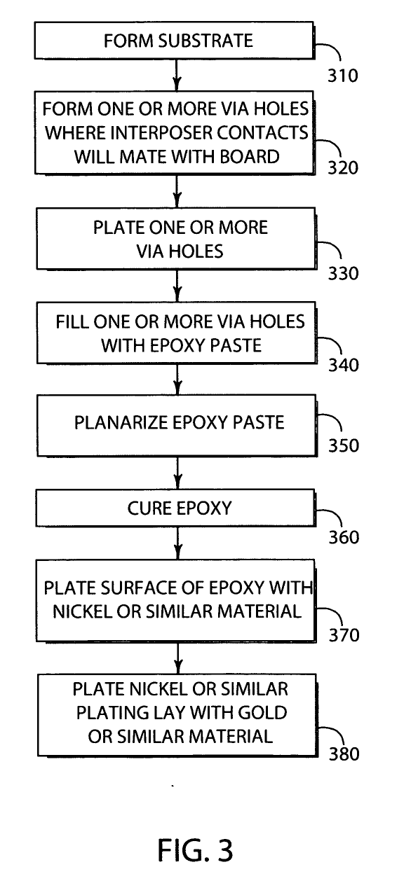

With specific reference to FIG. 3, a method in accordance with the present teachings is illustrated. During manufacture, after the high temperature substrate 250 is formed (310), a large via hole 260 may be drilled or otherwise formed (320) directly where an interposer contact 200 will make contact on the land pad 210. Next, the via 260 may be plated (330) with copper or a similar material 230 by electro-plating or any known plating process and filled (340) with an epoxy paste 240. Next the epoxy paste may be made substantially flat (350) relative to the outer surface of the printed circuit board by use of a wiping process or any known sanding or planing procedure before the epoxy is cured (360). Next a nickel plating layer 220 may be added (370) by any known plating means and finally a gold plating layer 210 may be added (380) to form the land pad substantially directly over the via 260. Gold is a noble metal and thus creates an excellent surface for conducting electrical signals. This will create a very durable surface which can be mated to the interposer contact 200. It will be appreciated by those skilled in the art, that other noble metals or materials with similar properties may be used, depending on the cost and desired characteristics of the land pad 210.

The present teachings permit the printed circuit board 250 to be approximately up to two times thicker than prior printed circuit boards and thus have more signal layers for routing by placing the via holes 260 substantially directly under and substantially in the center of the land pads 210 and filling the via holes 260 sufficiently so that it is flat enough to mate to an interposer. This invention saves valuable printed circuit board 250 real estate by placing the land pad 210 directly on top of the via hole 260 and substantially eliminates much of the space previously taken up by the dog bone trace and the land pad.

As the via hole 260 is now drilled in the substrate substantially directly under and in essentially the center of the land pad 210, the via 260 may be of a substantially larger diameter than prior via holes. This will, in turn, permit the printed circuit board 250 to be thicker, since the maximum thickness of the printed circuit board 250 is a function of the via hole 260 diameter. Standard plating processes permit the printed circuit board to be fifteen to thirty-six times thicker than the smallest via hole diameter on the board. Permitting the printed circuit board 250 to be thicker, further enables more layers within the board thickness, which will allow for more routing layers and thus a higher density of signals can be routed to the contact area underneath the interposer contacts. There may also be additional ground layers between signal routing layers of the printed circuit board 250 to improve crosstalk of signals from adjacent layers that may previously not have had a ground layer between them due to the limitation in board thickness. For example, typical via holes are 6 mils to 20 mils in diameter and via holes according to the present invention may be 15 mils to 35 mils in diameter.

The via structure of the present teachings enables more layers within the printed circuit board 250 that mates to the tester interposer by increasing the size of the via holes 260 for the signals. Also, larger via holes 260 can carry more current more reliably than smaller via holes. The signal fidelity may also be improved by placing additional ground layers in the printed circuit board 250, which is able to be thicker with larger via holes 260. This may improve crosstalk between signals on adjacent layers. The additional ground layers may also be used to create controlled impedance transmission lines in the printed circuit board 250.

While the invention had been particularly shown and described with reference to specific embodiments, it will be readily appreciated by those skilled in the art that changes in the form and details of the disclosed embodiments may be made without departing from the spirit or scope of the invention. For example, some of the descriptions of embodiments herein imply a certain orientation of various assemblies of which the system is constructed or a certain order of fabricating or mounting the assemblies. For example, the surface planing may be completed before the epoxy material is cured. It will be understood, however, that the principles of the present invention may be employed in systems having a variety of spatial orientations or orders of fabrication or mounting and that therefore, the invention should not be limited to the specific orientations or orders of fabrication or mounting disclosed herein.

1. A device comprising:
a substrate;
at least one via hole in the substrate;
an epoxy with a coefficient of thermal expansion substantially similar to that of the substrate filling the at least one via hole; and
a land pad on an upper surface of the epoxy filling the at least one via hole.

2. The device according to claim 1, wherein the land pad is a noble metal land pad.

3. The device according to claim 2, wherein the noble metal land pad comprises gold.

4. The device according to claim 3, wherein the noble metal land pad comprises a first layer of nickel plating and a second layer of gold plating.

5. The device according to claim 2, wherein the noble metal land pad comprises a layer of nickel plating on an upper surface of the epoxy filling the at least one via hole and a layer of gold plating on the layer of nickel plating, wherein the layer of nickel plating and the layer of gold plating are substantially directly over the at least one via hole.

6. The device according to claim 1 further comprising:
plating between the at least one via hole in the substrate and the epoxy filling the at least one via hole.

7. The device according to claim 1, wherein the plating between the at least one via hole in the substrate and the epoxy filling the at least one via hole is metal.

8. The device according to claim 1, wherein the epoxy filling the at least one via hole comprises copper epoxy.

9. A device comprising:
a high temperature substrate;
at least one via hole in the high temperature substrate;
a copper plating in the at least one via hole;
a copper epoxy filling the at least one via hole;
a nickel plating on an upper surface of the copper epoxy filling the at least one via hole; and
a gold plating on the nickel plating, wherein the gold plating creates a land pad substantially directly over the at least one via hole.

10. A system comprising:
an ATE tester;
an interposer with a contact; wherein the interposer is electrically and mechanically connected to the ATE tester; and
a printed circuit board with a via hole having a metal epoxy filling and a noble metal land pad substantially directly over the epoxy filling; wherein the interposer contact is electrically and mechanically in contact with the noble metal land pad on the via hole of the printed circuit board; wherein the interposer contact creates an electrical connection between the printed circuit board and the ATE tester via the land pad substantially directly over the via hole.

11. An electrical contact between a component on a printed circuit board and an interposer of an ATE tester, the electrical contact comprising:
a via in the printed circuit board, wherein the via is connected to the component on the printed circuit board;
a metal plating in the via;
an epoxy filling the via, wherein the metal plating is between the epoxy and the via; and
a metal land pad on a top surface of the printed circuit board substantially directly over the via and in contact with the epoxy filling the via, the metal land pad configured to mate with an interposer contact of an ATE tester.

12. The electrical contact between a component on a printed circuit board and an interposer of an ATE tester according to claim 11, wherein the metal plating in the via comprises copper plating.

13. The electrical contact between a component on a printed circuit board and an interposer of an ATE tester according to claim 11, wherein the epoxy filling the via comprises copper epoxy.

14. The electrical contact between a component on a printed circuit board and an interposer of an ATE tester according to claim 11, wherein the metal land pad directly over the via comprises gold plating over nickel plating.

15. A method comprising:
(a) providing a high temperature substrate having a first side and a second side;
(b) forming a large via hole in the high temperature substrate;
(c) plating the large via hole;
(d) filling the plated large via hole with an epoxy paste;
(e) planarizing the epoxy paste with the first side of the high temperature substrate;
(f) curing the epoxy;
(g) creating a contact pad on the epoxy on the first side of the high temperature substrate.

16. A method in accordance with claim 15, wherein step (c) of plating the large via hole further comprises plating the via hole with copper.

17. A method in accordance with claim 15, wherein the large via hole is approximately 15 mils to 35 mils in diameter.

18. A method in accordance with claim 15, wherein the epoxy in step (d) comprises a copper epoxy paste.

19. A method in accordance with claim 15, wherein step (g) further comprises plating the epoxy on the first side of the high temperature substrate with a noble metal contact pad.

20. A method in accordance with claim 15, wherein step (g) comprises plating the epoxy on the first surface of the high temperature substrate with a first layer of nickel plating and a second layer of gold plating creating a contact pad.
